(19) United States
(12) Patent Application Publication
(10) Pub. No.: US 2010/0297781 A1
(43) Pub. Date: Nov. 25, 2010

(54) METHOD FOR MANUFACTURING MEMS STRUCTURES

(75) Inventor: Andreas Scheurle, Leonberg (DE)

Correspondence Address: KENYON & KENYON LLP, ONE BROADWAY, NEW YORK, NY, 10004, US

(73) Assignee: ROBERT BOSCH GMBH, Stuttgart (DE)

(21) Appl. No.: 12/308,530

(22) PCT Filed: May 23, 2007
(86) PCT No.: PCT/EP2007/054988

§ 371 Date: Aug. 9, 2010

(30) Foreign Application Priority Data
Jul. 12, 2006 (DE) 10 2006 032 195.2

(51) Int. Cl. H01L 21/20; H01L 21/66

(52) U.S. Cl. 438/5; 438/481; 257/E21.09; 257/E21.528

(57) ABSTRACT

A method for manufacturing MEMS structures having at least one functional layer of silicon that contains structures that are exposed by removing a sacrificial layer, at least one sacrificial layer and at least one functional layer being deposited such that they grow in a monocrystalline manner, and the sacrificial layer is made up of a silicon-germanium mixed layer.

### FIELD OF THE INVENTION

The present invention relates to a method for manufacturing MEMS structures (microelectromechanical systems) based on silicon, preferably MEMS structures that are able to be deposited in multiple layers.

### BACKGROUND INFORMATION

In particular for use in acceleration sensors or rotation-rate sensors that are based on capacitive methods of measurement (capacitive MEMS), such structures include essentially a conductive functional layer that contains fixed and movable regions. During manufacturing, movable regions are normally fixed by a so-called sacrificial layer, which is then selectively removed at the end of the manufacturing process by method steps known from micromechanics and semiconductor technology.

It is known to use sacrificial layers of silicon oxide in conjunction with epitaxially grown functional layers of polycrystalline silicon. This technology includes a subsequent setting of different layer parameters, in particular of the conductivity, of the functional layer by driving in a trivalent or pentavalent dopant. Moreover, the polycrystalline structure makes it necessary to compensate stress gradients caused by the manufacturing process in the movable regions of the functional layer through additional annealing steps to prevent these movable regions from deforming outside of the occurrence of intended loads. The method permits only relatively low etching rates and undercutting widths.

It is also known to replace the sacrificial layer of silicon oxide with a sacrificial layer of silicon-germanium. This may be selectively removed using CIF₃ gas-phase etching, for example. The etching rates and undercutting widths that are able to be achieved are clearly greater relative to the method having sacrificial layers of silicon oxide. However, germanium's diffusion behavior, which causes germanium to diffuse out of the sacrificial layer into the functional layer in process steps having longer-lasting thermal loading, for example, when driving in required dopants, is problematic. The resulting layer fusions may alter the originally formed structures and impair their operativeness.

It is known to reduce this problem in structures of polycrystalline layers by surrounding the sacrificial layer with a diffusion barrier against germanium. However, this means an additional method step that, depending on the structure, in particular if contact holes to “buried circuit traces” are required, entails sometimes considerable additional effort and is associated with corresponding additional costs.

An additional disadvantage of the methods mentioned is the generally very sensitive compensation of stress gradients by driving in dopants. The success of this compensation is sensitively dependent on the avoidance of later thermal overloadings of the doped layers, which is why, in a desired integration of several sensor elements into one chip, the sensor elements must be offset laterally to thermally uncouple them during manufacturing. This results in increased space requirements and costs of the MEMS structure and of the finished component.

### SUMMARY OF THE INVENTION

An objective of the present invention is to provide a method that allows for a highly effective manufacturing of complex MEMS structures in a tight space and avoids the disadvantages of the related art.

This objective is achieved by a method according to the present invention.

The method according to the present invention is based on the deposition of substantially monocrystalline functional and sacrificial layers. Evidently, the associated elimination of the grain boundaries results in an effective hindrance in particular of the diffusion of germanium. This makes it possible to use sacrificial layers of silicon-germanium without having to deposit an additional barrier against germanium to restrict its diffusion. The method is applied in the manufacture of MEMS structures having at least one functional layer of silicon, which layer contains structures that are exposed by removing a sacrificial layer. According to the present invention, at least one sacrificial layer and at least one functional layer are deposited such that they grow in a monocrystalline manner, the sacrificial layer being made up of a silicon-germanium mixed layer.

Advantageously, multiple functional layers and sacrificial layers are deposited on top of each other, all functional layers and all sacrificial layers being deposited such that they grow in a monocrystalline manner, and the sacrificial layers respectively being made up of a silicon-germanium mixed layer. It is possible to deposit repeatedly since due to the relatively high growth rates the warming of the assemblage as a whole requires only a relatively short period of time, in which a diffusion of germanium, which is additionally hindered by missing grain boundaries, may be disregarded. The sacrificial material is advantageously removed by CIF₃ gas-phase etching. Thus, it is possible to make use of the advantages of large undercutting widths and high etching speeds without the additional effort of depositing an additional insulating layer to prevent the diffusion of germanium.

Process parameters are advantageously adjusted accordingly, at least intermittently, such that the epitaxial growth takes place at a growth speed of at least 3 μm/min.

If it is necessary to adjust the conductivity of the silicon layers, it is advantageous to do so by in situ doping. In this way, it is possible to avoid stress gradients.

The alternation between silicon layers and silicon-germanium mixed layers makes it easier to prevent incorrect etching depths, and thus the occurrence of faulty structures, by monitoring the plasma emission and/or mass-spectroscopically detectable species.

To achieve the advantageous effects of the method according to the present invention, at least the following steps should be included:
preparing an SOI wafer (silicon on insulator) having a monocrystalline starting layer of silicon,
structuring the monocrystalline starting layer of silicon,
epitaxial depositing of a sacrificial material in the form of monocrystalline silicon-germanium,
structuring the monocrystalline sacrificial layer,
epitaxial depositing of a functional layer of monocrystalline silicon,
structuring the functional layer of monocrystalline silicon,
repeated epitaxial depositing of the sacrificial material in the form of monocrystalline silicon-germanium,
structuring the most recently deposited monocrystalline sacrificial layer,
epitaxial depositing of a cap layer of monocrystalline silicon,
complete structuring of the cap layer up to the most recently deposited sacrificial layer,
removing the sacrificial material,
closing the openings in the cap layer.

Depending on requirements and the complexity of the desired functional structure, it is possible to repeat the steps of the deposition and structuring of a sacrificial layer and the deposition and structuring of a functional layer several times before closing with a cap layer.

Advantageously, it is possible to adjust individual layers to one another via marks inserted in the wafer edge. If the first etching immediately exposes an oxide surface that is so large that it does not grow shut during the following epitaxial processes, marks may be placed there that are accessible throughout the entire manufacturing of the MEMS structure. It is advantageous to use selective epitaxy for this purpose. To this end, the process parameters are adjusted such that no depositing occurs on silicon oxide.

### BRIEF DESCRIPTION OF THE DRAWINGS

FIG. 1 shows an unstructured SOI wafer.

FIG. 2 shows an SOI wafer having a structured starting layer.

FIG. 3 shows an SOI wafer having an additional first structured sacrificial layer.

FIG. 4 shows an SOI wafer having a first structured functional layer.

FIG. 5 shows an SOI wafer having a second structured functional layer.

FIG. 6 shows an SOI wafer having a closed cap layer.

FIG. 7 shows an SOI wafer having a completely exposed functional structure.

FIG. 8 shows an SOI wafer having a sealed and bonded MEMS structure.

### DETAILED DESCRIPTION

FIG. 1 shows an unstructured SOI wafer as starting material for the manufacturing of MEMS structures that may be deposited in multiple layers. Such a wafer is made up of a thick silicon layer 1 that simultaneously serves as a mechanical support, on which a silicon oxide layer is deposited as insulation layer 2. A monocrystalline starting layer 3 of silicon is situated on top of insulation layer 2. On such SOI wafers, it is possible to produce, by appropriate structuring, individual regions that are electrically insulated from one another and that may be used as a starting layer for subsequent epitaxial growing of additional layers.

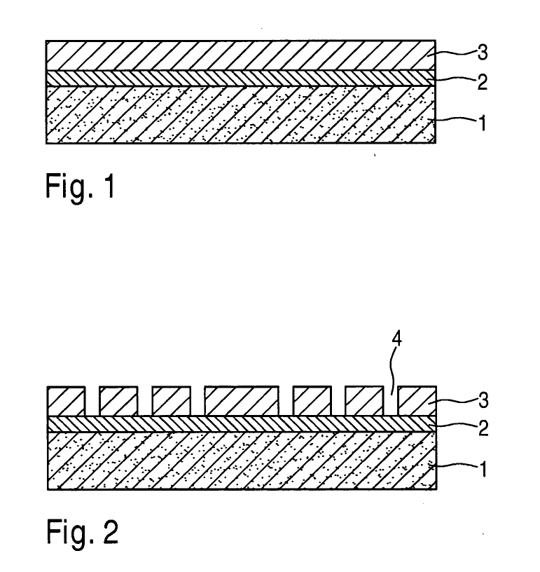

FIG. 2 shows an SOI wafer having a structured starting layer 3. The structuring is effected via an etching step. In the present case, several regions of starting layer 3 are electrically insulated from one another since etched trenches 4 extend to insulation layer 2. The individual regions of starting layer 3 that are exposed in this way form the pedestals of the subsequent MEMS structures.

It is also possible to define conductive connections between individual structures. To this end, the silicon layer must often have a particular conductance. It is possible to adjust the conductance by doping the silicon. To avoid layer stress and conductance fluctuations within the structures, the conductance of starting layer 3 is maintained by in situ doping when depositing additional layers. It is possible to avoid a subsequent doping and thermal overloading of individual structure regions in this way.

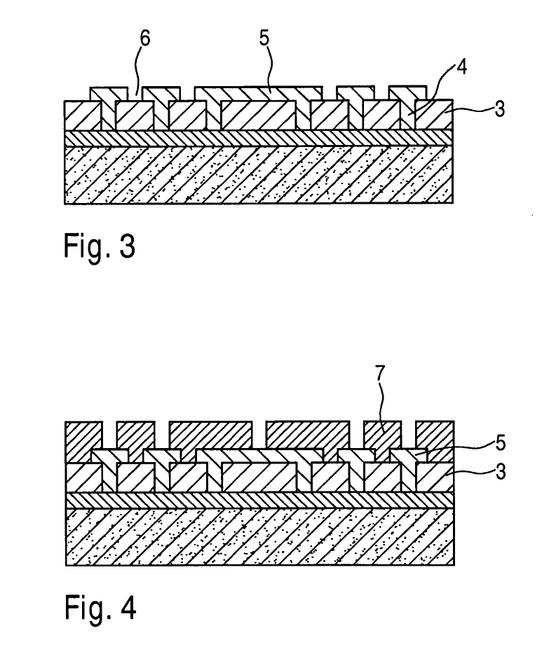

If starting layer 3 is structured from monocrystalline silicon, sacrificial material is deposited in the form of monocrystalline silicon-germanium. For this purpose, the surface of the silicon regions remaining after the structuring of starting layer 3 is used as a starting layer for growing an initially continuous sacrificial layer 5 so as to permit epitaxial growth. For example, a CMP step (chemical-mechanical polishing) adjusts exactly the thickness of sacrificial layer 5, which is decisive for the extension of hollow spaces that are subsequently to be formed in the finished functional structure, as a result of which a polished surface is available that in turn is able to serve as a starting structure for additional epitaxial growth. FIG. 3 furthermore shows that etched trenches 4 from the previous structuring are filled with the sacrificial material. An etching step subsequently structures polished sacrificial layer 5 to produce contact holes 6 to individual regions of starting layer 3, which may be used as a pedestal or circuit trace. To avoid etching too deep, the plasma emission may be monitored during this process step. If emission lines indicating a presence of germanium disappear, then this indicates that sacrificial layer 5 has been structured through, and the etching process is terminated.

FIG. 4 shows an SOI wafer having a first structured functional layer 7 of monocrystalline silicon. This is first deposited epitaxially on sacrificial layer 5, and subsequently structured in a trench process. Since there is no layer that brings etching to a halt, and an excessive over-etching could under certain circumstances produce unwanted connections between conductive regions, the etching depth should always be monitored in this process step. For example, this may be done by a mass spectrometer, to which the exhaust gases of the trencher are fed. If germanium is detected, the etching process is terminated. This step results in a structured functional layer 7 whose regions partially rest on the sacrificial layer, and are partially electroconductively connected to regions of starting layer 3.

The steps indicated in FIGS. 3 and 4 of the deposition and structuring of a sacrificial layer and of the deposition and structuring of a functional layer may be repeated multiple times so as to place multiple structures on top of one another until a desired functional structure is formed. Thus, for example, it is possible to mount acceleration sensors on top of one another on one chip such that the detection directions of the acceleration sensors are offset by 90°, which results in two-axis acceleration sensors without enlarging the chip surface. Furthermore, it is possible to implement cascaded structures. Thus, it is possible to produce rotation-rate sensors whose detection structures (acceleration sensors) are disposed on or under an oscillator.

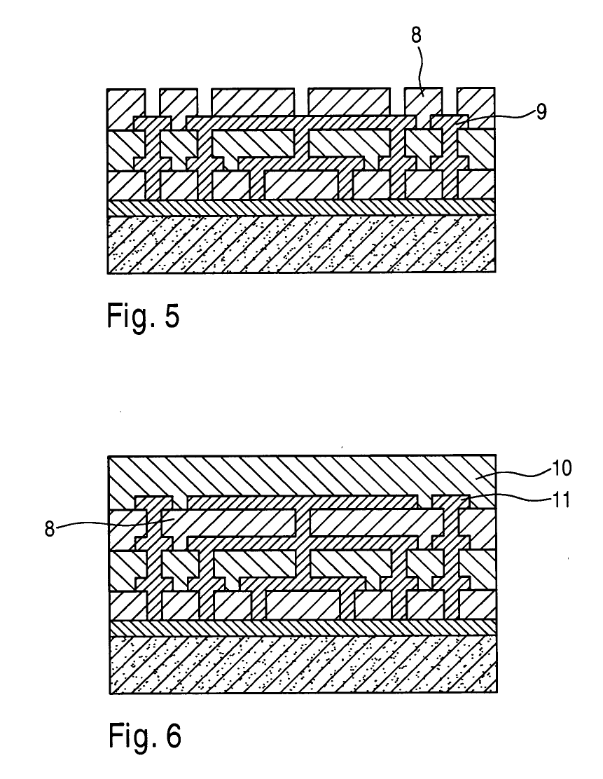

FIG. 5 shows an SOI wafer having a second structured functional layer 8 of monocrystalline silicon, and a second sacrificial layer 9 of monocrystalline silicon-germanium. In this context, it is important for the structuring to take place in such a way that the zones filled by the sacrificial material each form contiguous regions that are able to be reached through the last silicon layer.

FIG. 6 shows an SOI wafer having a continuous cap layer 10. A last sacrificial layer 11 of monocrystalline silicon-germanium, which is perforated in places where a bonding is to take place later, is located between cap layer 10 and topmost functional layer 8. After the functional structure is completely formed, the last sacrificial layer 11 is deposited and structured, and cap layer 10 is deposited.

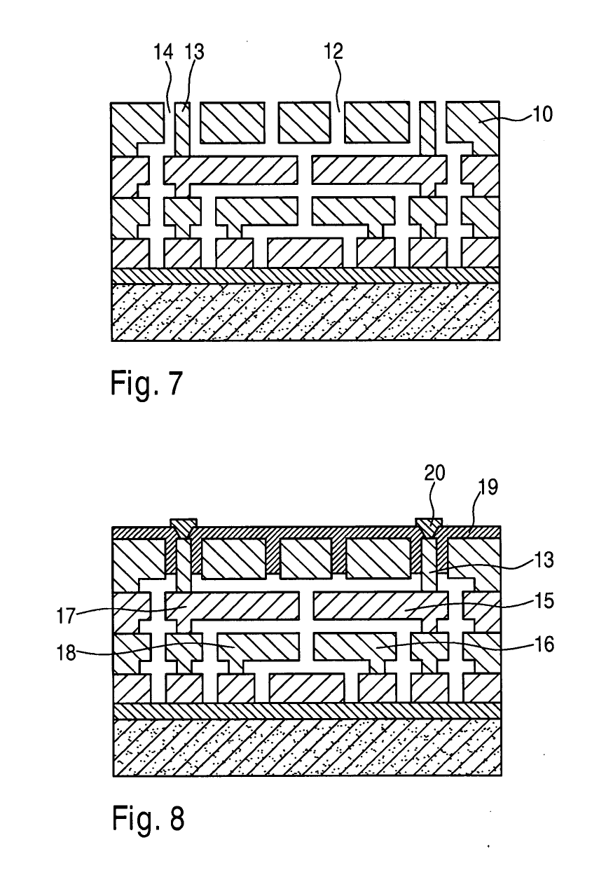

Subsequently, accesses 12 are structured in cap layer 10 in accordance with FIG. 7, via which the entire sacrificial material may be dissolved out through CIF₃ gas-phase etching. The mechanical operability of the functional structures is produced in this manner.

For this purpose, one must keep in mind that structures 13, which are to be used for a subsequent bonding of the MEMS structures, must also be separated from the rest of cap layer 10, which may be done by etching a ring-shaped access 14. If instabilities of individual structures would result in this case, ring-shaped accesses 14 could also be opened prior to opening remaining accesses 12 in the cap layer. In this case, ring-shaped accesses 14 would have to be closed by an insulating material, which would simultaneously serve to support the structure to be stabilized, before starting to dissolve out the sacrificial material by CIF₃ gas-phase etching. In the case of sufficiently stable structures, it is possible to do without this form of repeated structuring of cap layer 10, which means that all required accesses 12, 14 may be opened in one process step by etching.

Once the sacrificial material is removed, cap layer 10 is hermetically sealed again. FIG. 8 shows a section of an SOI wafer having a sealed and bonded MEMS structure. It has, for example, four mechanically deflectable structures 15, 16, 17, 18, of which two are respectively disposed one upon the other. The accesses required for dissolving out the sacrificial material in cap layer 10 were presently sealed hermetically by the plasma-supported, non-conformal deposition of an oxide 19 at a low temperature on the basis of silane or TEOS, for example. The plasma-supported deposition of oxide makes it possible to ensure that through the appropriate setting of the plasma parameters in coordination with the geometrical boundary conditions of the accesses in cap layer 10, an excessively deep intrusion of the plasma into the structural cavities does not occur. This prevents oxide from possibly being deposited in more deeply situated regions and modifying mechanical properties of the system.

Bond pads 20 on structures 13, which are used for bonding, are preferably processed with the aid of sputter technology prior to separating the component having the MEMS structure manufactured according to the present invention.

1-10. (canceled)

11. A method for manufacturing MEMS structures having at least one functional layer of silicon, which layer contains structures that are exposed by removing a sacrificial layer, the method comprising:
depositing at least one sacrificial layer and at least one functional layer such that they grow in a monocrystalline manner, the at least one sacrificial layer being made up of a silicon-germanium mixed layer.

12. The method according to claim 11, wherein multiple functional layers and sacrificial layers are deposited one upon the other, all functional layers and all sacrificial layers being deposited such that they grow in a monocrystalline manner, the sacrificial layers being respectively made up of a silicon-germanium mixed layer.

13. The method according to claim 11, further comprising:
preparing an SOI wafer having a monocrystalline starting layer of silicon;
structuring the monocrystalline starting layer of silicon;
epitaxial depositing of a sacrificial material in the form of monocrystalline silicon-germanium;
structuring the monocrystalline sacrificial layer;
epitaxial depositing of a functional layer of monocrystalline silicon;
structuring the functional layer of monocrystalline silicon;
repeated epitaxial depositing of the sacrificial material in the form of monocrystalline silicon-germanium;
structuring a most recently deposited monocrystalline sacrificial layer;
epitaxial depositing of a cap layer of monocrystalline silicon;
complete structuring of the cap layer up to the most recently deposited sacrificial layer;
removing the sacrificial material; and
closing openings in the cap layer.

14. The method according to claim 11, further comprising carrying out an in situ doping when depositing the functional layer.

15. The method according to claim 11, further comprising adjusting process parameters, at least intermittently, such that epitaxial growth takes place at a growth rate of at least 3 μm/min.

16. The method according to claim 15, wherein the process parameters are adjusted such that no depositing occurs on silicon oxide.

17. The method according to claim 11, further comprising removing sacrificial material by CIF₃ gas-phase etching.

18. The method according to claim 11, further comprising exposing and surrounding electric penetrations through a cap layer by an insulating material prior to a complete removal of sacrificial material.

19. The method according to claim 11, further comprising closing openings in a cap layer by non-conformal oxide deposition.

20. The method according to claim 11, further comprising, during a structuring, monitoring at least one of (a) a plasma emission and (b) mass-spectroscopically detectable species, to prevent an incorrect etching depth.
